(19) United States
(12) Patent Application Publication
(10) Pub. No.: US 2012/0025214 A1
(43) Pub. Date: Feb. 2, 2012

(54) LED PACKAGING STRUCTURE AND PACKAGING METHOD

(75) Inventors: Chenghai RUAN, Guangzhou City (CN); Zhaoming ZENG, Guangzhou City (CN); Haiying CHEN, Guangzhou City (CN); Guowei David XIAO, Guangzhou City (CN)

(73) Assignee: APT ELECTRONICS LTD., Guangzhou City (CN)

(21) Appl. No.: 13/020,466

(22) Filed: Feb. 3, 2011

(30) Foreign Application Priority Data
Jul. 30, 2010 (CN) 201010243390.7

(51) Int. Cl. H01L 27/15; H01L 33/56

(52) U.S. Cl. 257/88; 257/98; 438/27; 257/E27.12; 257/E33.073; 257/E33.059

(57) ABSTRACT

The present invention relates to an LED packaging structure and packaging method. Said packaging structure includes a substrate, an LED chip, one or more convex walls and a colloid lens shaped by the restriction of the convex walls. Said convex walls are arranged on the substrate, at least one LED chip is arranged on the substrate within an area surrounded by the convex walls, and the colloid lens enclosing the LED chip is arranged within the area surrounded by the convex walls. The colloid lens is formed with desired colloid shape by placing a liquid colloid within the area confined by the convex walls and utilizing surface tension of the liquid, and is cured. Compared to prior art, the LED packaging structure of the present invention is simple and reasonable, with simple production process and lower costs.

### CROSS-REFERENCE TO RELATED APPLICATION

The present application claims priority of Chinese Patent Application CN201010243390.7 filed Jul. 30, 2010, the entire contents of which is incorporated herein by reference.

### FIELD OF THE INVENTION

The present invention belongs to the field of manufacturing a photoelectric device, and relates to an LED packaging structure and manufacturing method thereof.

### BACKGROUND OF THE INVENTION

The light emitting diode (LED) source has several advantages of high efficiency, long life and no harmful substances such as Hg and the likes. With the rapid development of LED technology, the LED's properties, such as brightness, lifetime and the likes, have been greatly improved, such that it has found an increasing application in a variety of areas ranging from outdoor lighting such as street lamps to indoor lighting such as decorative lights, in which the LED is used or replaced as a light source.

In the LED packaging structure, in order to enhance the brightness of the LED and achieve a better effect of reliability, silicone, epoxy resin or the likes is usually used to form a lens of hemispherical or other shapes in the LED surface, to enhance the light extracting rate of the LED. Currently, the lens in the LED surface is formed primarily by two packaging processes. One is to form the lens in the LED surface by a mold, and the other is to firstly form the lens by injection molding, and then to adhere the Tens on the LED surface by coating or applying colloid.

As an example, a power LED with a lens molded by injecting colloid at the bottom, and manufacturing method thereof are disclosed in China patent application of publication number CN101162750, including the steps of: arranging plastic injection and vent holes on a substrate; installing an LED chip to the substrate and completing electrical connections; then pressing a mold for lens molding on the substrate; injecting an encapsulant colloid from the plastic injection holes at the bottom of the substrate; after completion of the colloid injection, curing the colloid and removing the mold; and completing the molding of the package lens of the LED chip. However, this manufacturing method needs to use the mold for lens molding, and the production process is relatively complex. If an automatic machine is used for molding, the investment in the machine will be very high, but productivity is low; if a simple jig is used for molding, it is difficult to control the quality of the lens and LED packaging process.

As another example, a packaging method for a high power white LED is disclosed in China patent application of publication number CN10101404317, including the steps of: step 1 of providing two sheets of electrodes and a base for installing the two sheet of electrodes; step 2 of fixing an LED chip within the above base and baking it; step 3 of bonding wires to connect positive and negative poles of the LED chip to said two sheet of electrodes respectively; step 4 of covering said base with a lens and adhering the lens to the base; and step 5 of baking the above components to achieve a fixed shape. However, this packaging method of adhering the injection molding lens to the surface of the LED chip will produce an interface between the lens and the packaging materials, which will cause a certain loss in the light extracting rate; and the interface between different materials will also cause the issues such as light attenuation etc., due to the problems such as thermal mismatch etc., in the process of long-term use; at the same time, there are also problems with this packaging method in the process of production, for example it is difficult to control the packaging quality and achieve automatic production.

### SUMMARY OF THE INVENTION

The object of the invention is to provide an LED packaging structure with low cost, controllable quality and direct shaping without mold, in order to overcome the shortcomings and deficiencies of prior art.

Meanwhile, the present invention also provides a packaging method for said LED packaging structure.

AN LED packaging structure includes a substrate, an LED chip, one or more convex walls and a colloid lens shaped by the restriction of the convex walls. Said convex walls are arranged on the substrate, at least one LED chip is arranged on the substrate within an area surrounded by the convex walls, and the colloid lens enclosing the LED chip is arranged within the area surrounded by the convex walls. The colloid lens is formed with desired colloid shape by placing a liquid colloid within the area confined by the convex walls and utilizing surface tension of the liquid, and is cured.

AN LED packaging method includes the steps of:

S1: forming a convex wall on a substrate;

S2: fixing at least one LED chip onto the substrate within a confined area formed by the convex wall;

S3: dispensing a colloid above the confined area formed by the convex wall, and forming a colloid lens to isolate the LED chip from environment.

Compared to prior art, the LED packaging structure of the present invention is simple and reasonable, and is easy to produce and improve yield.

Compared to prior art, the LED packaging method of the present invention can directly conducts dispensing process above the LED chip, and simultaneously uses a structure of the convex walls to prevent the encapsulant colloid fluid from extending outwardly thereby to form the encapsulant colloid lens of regular shape, with the process simple and the quality controllable. At the same time, it is suitable for wafer level packaging with high packaging efficiency and low production costs.

In order to more clearly understand the present invention, the implementations of the invention will be set forth in conjunction with the drawings hereinafter.

### BRIEF DESCRIPTION OF THE ACCOMPANYING DRAWINGS

FIG. 1 is a cross section schematic view of first embodiment of the LED packaging structure of the present invention.

FIG. 2 is a top view of the LED packaging structure shown in FIG. 1.

FIGS. 3a, 3b and 3c are cross section schematic views of the packaging structure in various steps in the packaging flow of first embodiment of the LED packaging structure of the present invention.

FIG. 4 is a top view of f the LED packaging structure of the present invention on a wafer.

FIG. 5 is a cross section schematic view of second embodiment of the LED packaging structure of the present invention.

FIG. 6 is a top view of the LED packaging structure shown in FIG. 5.

FIG. 7 is a cross section schematic view of third embodiment of the LED packaging structure of the present invention.

FIG. 8 is a top view of the LED packaging structure shown in FIG. 7.

### DETAILED DESCRIPTION OF PREFERRED EMBODIMENTS

### Embodiment 1

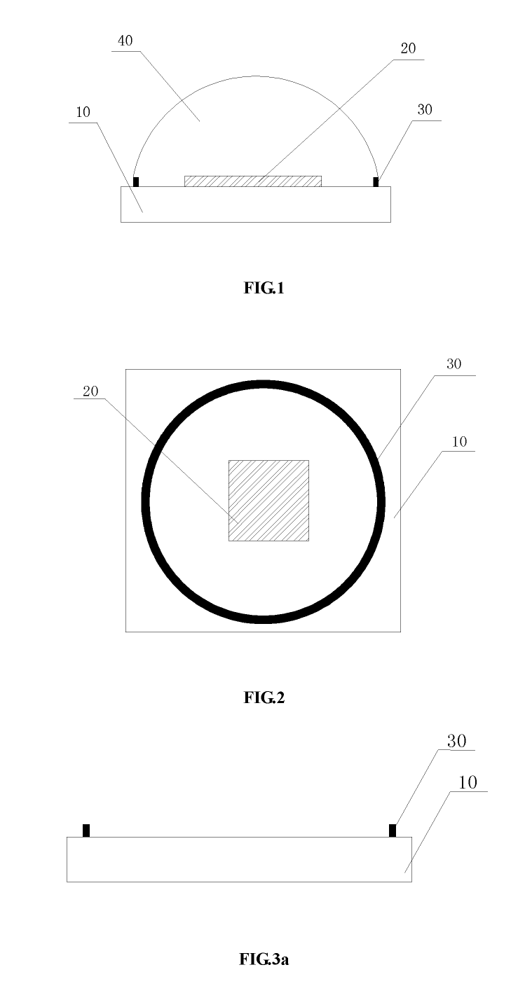

Now refer to FIGS. 1 and 2, wherein FIG. 1 is a cross section schematic view of first embodiment of the LED packaging structure of the present invention, and FIG. 2 is a top view of the LED packaging structure shown in FIG. 1. The LED packaging structure includes a substrate 10, an LED chip 20, a convex wall 30 and a colloid lens 40. The convex wall 30 is arranged on the substrate 10 to form a confined area, and at least one LED chip 20 is arranged within the confined area of the convex wall 30 and fixed onto the substrate 10. The colloid lens 40 is arranged on the surface of said LED chip 20 and encloses the LED chip 20.

In particular, said substrate 10 can be silicon wafer, ceramic plate, printed circuit board (PCB), metal-based printed circuit board (MCPCB) or glass sheet.

Said convex wall 30 has a width of 10 um˜5000 um and a height of 5 um˜5000 um. Said convex wall 30 can be an arc ring, a polygon ring, a ring surrounded by a combination of arc and polygon, or an intermittent type of enclosed structure. The material of said convex wall is silicone, epoxy resin, metal, oxide, nitride, polyimide, photoresist permanently usable after being cured, or a mixture thereof.

The material of said colloid lens is epoxy resin, silicone, modified material of epoxy or silicone, or a mixture of the above and phosphor.

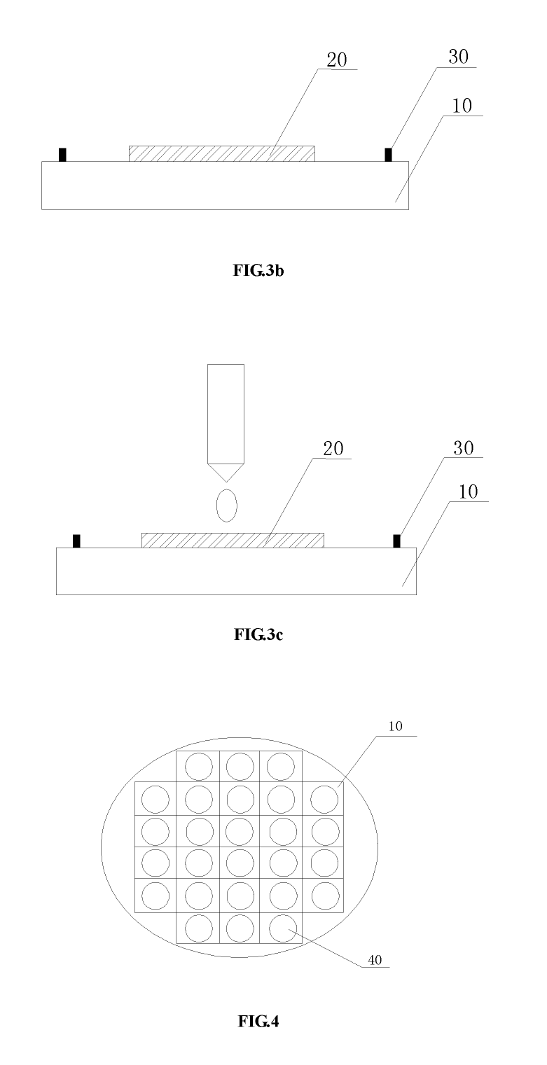

Refer to FIGS. 3a, 3b and 3c, which are cross section schematic views of the packaging structure in various steps in the packaging flow of the LED packaging structure of the present invention. The LED packaging structure of the present invention can be formed by the following steps:

S1: a convex wall 20 is formed on the substrate 10. The convex wall 30 can be formed by a process of lithography shaping, or by a process of first performing a convex wall 30 and then adhering the convex wall 30 onto the substrate 10.

S2:at least one LED chip 20 is fixed to the substrate 10 and located within the confined area formed by the convex wall 30.

S3: a colloid lens 40 is formed on the substrate 10. In particular, dispensing process is conducted above the confined area formed by the convex wall 30, and a colloid drops onto the substrate 10 within the confined area to enclose the LED chip 20. At the same tune, as the colloid is liquid, the convex wall 30 limits outward expansion of the colloid at this time; and due to the surface tension of the colloid, a sphere-like colloid lens 40 is formed on the LED chip 20 after the colloid is cured. In this packaging step, a variety of colloid lenses 40 with sphere-like surface and different sizes can be formed according to the colloid characteristic and by controlling the dispensing amount, thereby to achieve various light emitting effect.

Refer to FIG. 4, which is a top view of f the LED packaging structure of the present invention on a wafer. In the packaging process of the present invention, multiple LED package structures can be formed simultaneously on a wafer, which can have a size of 2 inches to 12 inches. The LED packaging structure also can be formed on the ceramic substrate, the metal-based PCB substrate. The ceramic substrate or metal-based PCB substrate has an unlimited size. On the same wafer or the same piece of substrate, with the same process, the size of the LED packaging structure can be adjusted according to design requirements, and then the singulation process is conducted thereby to improve production efficiency.

### Embodiment 2

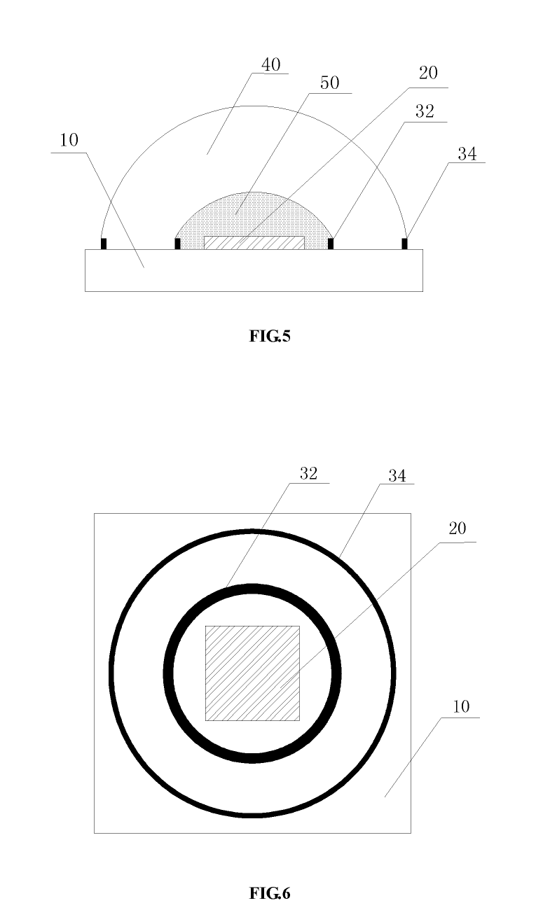

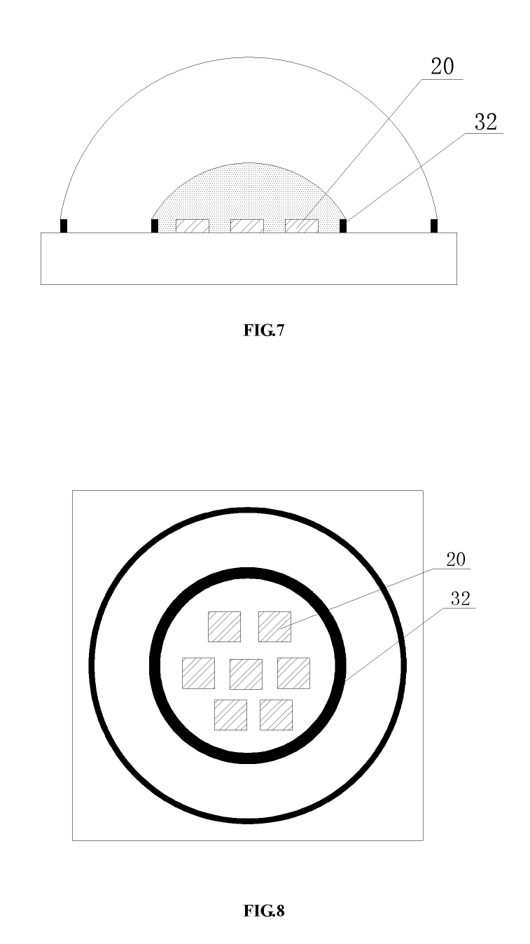

Refer to FIGS. 5 and 6, wherein FIG. 5 is a cross section schematic view of second embodiment of the LED packaging structure of the present invention, and FIG. 6 is a top view of the LED packaging structure shown in FIG. 5. The LED packaging structure of the second embodiment is roughly the same as the LED packaging structure of the first embodiment except that: an inner convex wall 32 and an outer convex wall 34 are arranged on the substrate 10, and the radius of the outer convex wall 34 is greater than that of the inner convex wall 32. One LED chip 20 is arranged within the confined area of the inner convex wall 32 and fixed onto the substrate 10. The inner convex wall 32 is used to coat a phosphor layer 50 formed by phosphor and silicone, while the outer convex wall 34 is used for shaping package of the colloid lens 40. Both the phosphor layer 50 and colloid lens 40 make use of the principle that a liquid is naturally shaped by the surface tension with the edges restricted by the convex walls. The number of the convex wall rings can not be limited, and depends on the needs of the process. The principle remains that the droplets are naturally shaped under the effect of surface tension in case annular convex walls are restricted.

### Embodiment 3

Refer to FIGS. 7 and 8, wherein FIG. 7 is a cross section schematic view of third embodiment of the LED packaging structure of the present invention, and FIG. 8 is a top view of the LED packaging structure shown in FIG. 7. The LED packaging structure of the third embodiment is roughly the same as the LED packaging structure of the second embodiment except that multiple LED chips 20 are arranged within the confined area of the inner convex wall 32 and fixed onto the substrate 10. Said multiple LED chips 20 can have the same size or different sizes. The multiple LED chips 20 can have various types, i.e. a multi-chip module composed of chipsets emitting different light.

Compared to prior art, the present invention directly conducts dispensing process on the LED chip to form an encapsulant colloid lens, and simultaneously uses a structure of the convex walls to prevent the encapsulant colloid fluid from extending outwardly thereby to form the encapsulant colloid lens of regular shape, with the process simple and the quality controllable. At the same time, it is suitable for wafer level packaging with high packaging efficiency and low production costs.

The present invention is not limited to the above implementations. If changes and variations of the invention are not departed from the spirit and scope of the invention, and these changes and variations fall within the scope of the claims of the invention and equivalent technology, then the present invention is also intended to encompass these changes and variations.

1. An LED packaging structure, comprising: a substrate, at least one LED chip, one or more convex walls and a colloid lens shaped by the restriction of the convex walls, wherein said convex walls are arranged on the substrate, and the material of said convex walls is oxide or nitride, the LED chip is arranged on the substrate within an area surrounded by the convex walls, and the colloid lens enclosing the LED chip is arranged within the area surrounded by the convex walls; the colloid lens is formed with desired colloid shape by placing a liquid colloid within the area confined by the convex walls and utilizing surface tension of the liquid, and is cured.

2. The LED packaging structure of claim 1, wherein said convex walls are an arc ring, a polygon ring, or a ring surrounded by a combination of arc and polygon.

3. The LED packaging structure of claim 2, wherein said convex walls are continuous or intermittent closed loop structures.

4. The LED packaging structure of claim 1, wherein said convex walls have a height of 5 um˜5000 um.

5. The LED packing structure of claim 1, wherein said convex walls have a width of 10 um˜5000 um.

6. The LED packaging structure of claim 1, wherein the material of said colloid lens is epoxy resin, silicone, modified material of epoxy or silicone, or a mixture of epoxy resin or silicone and phosphor.

7. The LED packaging structure of claim 1, wherein said substrate is silicon wafer, ceramic plate, printed circuit board, metal-based printed circuit board or glass sheet.

8. An LED packaging method, comprising the steps of:
S1: forming a convex wall on a substrate, and the material of said convex walls is oxide or nitride;
S2: fixing at least one LED chip onto the substrate within a confined area formed by the convex wall; and
S3: dispensing a colloid above the confined area formed by the convex wall, and forming a colloid lens to isolate the LED chip from environment.

9. The packaging method of claim 8, wherein the convex wall is formed on the substrate by a lithography process.

10. The packaging method of claim 8, wherein the convex wall is first performed and then is adhered to the substrate.

11. The packaging method of claim 8, wherein said convex walls have a width of 10 um˜5000 um.

12. The packaging method of claim 8, wherein the material of said colloid lens is epoxy resin, silicone, modified material of epoxy or silicone, or a mixture of epoxy resin or silicone and phosphor.
